(19) United States
(12) Patent Application Publication
(10) Pub. No.: US 2025/0331301 A1
(43) Pub. Date: Oct. 23, 2025

(54) INTER-GATE CONTACTS FOR STACKED FIELD-EFFECT TRANSISTORS

(71) Applicant: International Business Machines Corporation, Armonk, NY (US)

(72) Inventors: Shay Reboh, Guilderland, NY (US); Wai Kin Li, Albany, NY (US); Nicholas Anthony Lanzillo, Wynantskill, NY (US); Utkarsh Bajpai, Delmar, NY (US); Prabudhya Roy Chowdhury, Albany, NY (US)

(21) Appl. No.: 18/637,576

(22) Filed: Apr. 17, 2024

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 84/0186; H10D 84/038; H10D 88/01

(57) ABSTRACT

A semiconductor device comprises a first transistor comprising a first gate region, and a second transistor comprising a second gate region, wherein the second transistor is stacked over the first transistor. A conductive contact is disposed between and contacts a surface of the first gate region and a surface of the second gate region, wherein the surface of the second gate region is disposed opposite the surface of the first gate region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming inter-gate contacts for stacked FETs.

In one embodiment, a semiconductor device includes a first transistor including a first gate region, and a second transistor including a second gate region, wherein the second transistor is stacked over the first transistor. A conductive contact is disposed between and contacts a surface of the first gate region and a surface of the second gate region, wherein the surface of the second gate region is disposed opposite the surface of the first gate region.

In another embodiment, a semiconductor device includes a first gate region, a second gate region stacked over the first gate region, and a dielectric layer disposed between the first gate region and the second gate region. A conductive contact is disposed in the dielectric layer between the first gate region and the second gate region, wherein the conductive contact contacts the first gate region and the second gate region.

In another embodiment, a semiconductor device includes a first nanosheet transistor including a first gate region, and a second nanosheet transistor including a second gate region, wherein the second nanosheet transistor is stacked over the first nanosheet transistor. A conductive contact is disposed between the first nanosheet transistor and the second nanosheet transistor. The conductive contact contacts a surface of the first gate region and a surface of the second gate region, wherein the surface of the second gate region is disposed opposite the surface of the first gate region.

These and other features and advantages of embodiments described herein will become more apparent from the accompanying drawings and the following detailed description.

### BRIEF DESCRIPTION OF THE DRAWINGS

FIG. 1A depicts a cross-sectional view of a semiconductor structure taken across gate structures following formation of a bottom level of transistors and dielectric placeholders for inter-gate contacts, according to an embodiment of the invention.

FIG. 1B depicts a cross-sectional view of a semiconductor structure taken along a gate structure following formation of a bottom level of transistors and dielectric placeholders for inter-gate contacts, according to an embodiment of the invention.

FIG. 1C depicts a cross-sectional view of a semiconductor structure taken across gate structures following formation of a bottom level of transistors and self-aligned contact (SAC) cap layers as placeholders for inter-gate contacts, according to an embodiment of the invention.

FIG. 1D depicts a cross-sectional view of a semiconductor structure taken along a gate structure following formation of a bottom level of transistors and combined dielectric and metal placeholders for inter-gate contacts, according to an embodiment of the invention.

FIG. 1E depicts a cross-sectional view of a semiconductor structure taken along a gate structure following formation of a bottom level of transistors and of inter-gate contacts, according to an embodiment of the invention.

FIG. 2A depicts a cross-sectional view of a semiconductor structure taken across gate structures following formation of a top level of transistors, according to an embodiment of the invention.

FIG. 2B depicts a cross-sectional view of a semiconductor structure taken along a gate structure following formation of a top level of transistors, according to an embodiment of the invention.

FIG. 2C depicts a cross-sectional view of a semiconductor structure taken across gate structures following formation of a top level of transistors, according to an embodiment of the invention.

FIG. 3 depicts a cross-sectional view of a semiconductor structure taken along a gate structure following removal of gate portions from the top level of transistors, according to an embodiment of the invention.

FIG. 4A depicts a cross-sectional view of a semiconductor structure taken across gate structures following removal of dielectric placeholders, according to an embodiment of the invention.

FIG. 4B depicts a cross-sectional view of a semiconductor structure taken along a gate structure following removal of dielectric placeholders, according to an embodiment of the invention.

FIG. 4C depicts a cross-sectional view of a semiconductor structure taken across gate structures following removal of SAC cap layers, according to an embodiment of the invention.

FIG. 4D depicts a cross-sectional view of a semiconductor structure taken along a gate structure illustrating removal of portions of gate dielectric layers and removal of dielectric placeholders, according to an embodiment of the invention.

FIG. 5A depicts a cross-sectional view of a semiconductor structure taken across gate structures following metal liner deposition, according to an embodiment of the invention.

FIG. 5B depicts a cross-sectional view of a semiconductor structure taken along a gate structure following metal liner deposition, according to an embodiment of the invention.

FIG. 5C depicts a cross-sectional view of a semiconductor structure taken across gate structures following metal liner deposition, according to an embodiment of the invention.

FIG. 6 depicts a cross-sectional view of a semiconductor structure taken along a gate structure following removal of metal liner portions from gate cut regions, according to an embodiment of the invention.

FIG. 7A depicts a cross-sectional view of a semiconductor structure taken across gate structures following dielectric material deposition in gate cut regions, inter-layer dielectric (ILD) layer deposition, contact formation and interconnect formation, according to an embodiment of the invention.

FIG. 7B depicts a cross-sectional view of a semiconductor structure taken along a gate structure following dielectric material deposition in gate cut regions, ILD layer deposition, contact formation and interconnect formation, according to an embodiment of the invention.

FIG. 7C depicts a cross-sectional view of a semiconductor structure taken across gate structures following dielectric material deposition in gate cut regions, ILD layer deposition, contact formation and interconnect formation, according to an embodiment of the invention.

FIG. 8 depicts a cross-sectional view of a semiconductor structure taken along a gate structure following removal of metal liner portions from bottom parts of gate cut regions, according to an embodiment of the invention.

FIG. 9A depicts a cross-sectional view of a semiconductor structure taken across gate structures following additional metal deposition for inter-gate contacts and dielectric material deposition in gate cut regions, according to an embodiment of the invention.

FIG. 9B depicts a cross-sectional view of a semiconductor structure taken along a gate structure following additional metal deposition for inter-gate contacts and dielectric material deposition in gate cut regions, according to an embodiment of the invention.

FIG. 9C depicts a cross-sectional view of a semiconductor structure taken across gate structures additional metal deposition for inter-gate contacts and dielectric material deposition in gate cut regions, according to an embodiment of the invention.

FIG. 10A depicts a cross-sectional view of a semiconductor structure taken across gate structures following ILD layer deposition, contact formation and interconnect formation, according to an embodiment of the invention.

FIG. 10B depicts a cross-sectional view of a semiconductor structure taken along a gate structure following ILD layer deposition, contact formation and interconnect formation, according to an embodiment of the invention.

FIG. 10C depicts a cross-sectional view of a semiconductor structure taken across gate structures following ILD layer deposition, contact formation and interconnect formation, according to an embodiment of the invention.

FIG. 11 depicts a cross-sectional view of an alternate embodiment to what is shown in FIG. 10B, where the metal of the inter-gate contact does not completely fill a cavity, according to an embodiment of the invention.

FIG. 12 depicts a cross-sectional view of a semiconductor structure taken along a gate structure where inter-gate contacts are formed through metal deposition through the same gate cut portion, according to an embodiment of the invention.

FIG. 13 depicts a cross-sectional view of an alternate embodiment to what is shown in FIG. 12, where the transistors include forksheet transistors, according to an embodiment of the invention.

### DETAILED DESCRIPTION

Illustrative embodiments of the invention may be described herein in the context of illustrative methods for forming inter-gate contacts for stacked FETs, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 3 to 20 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to area reduction (e.g., such as 30-40% area reduction for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

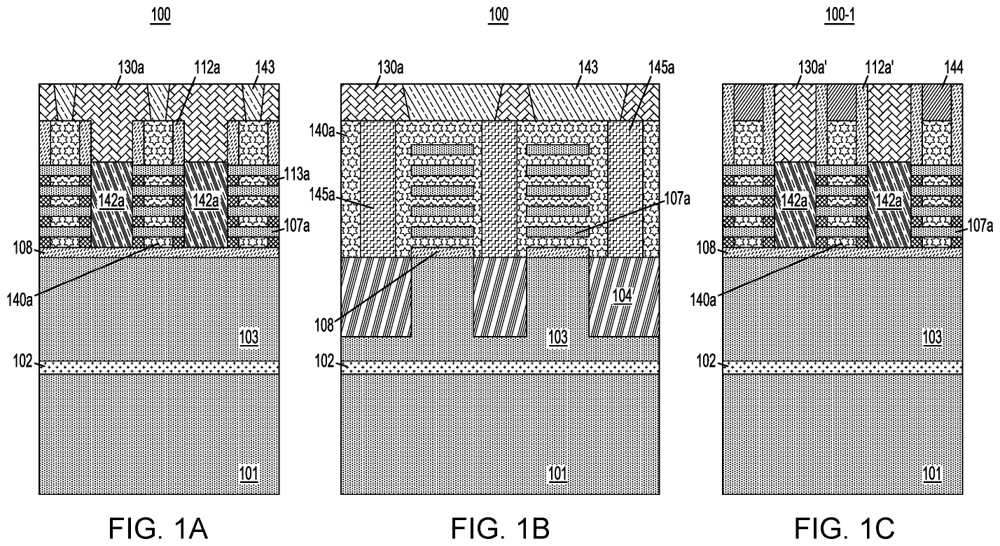

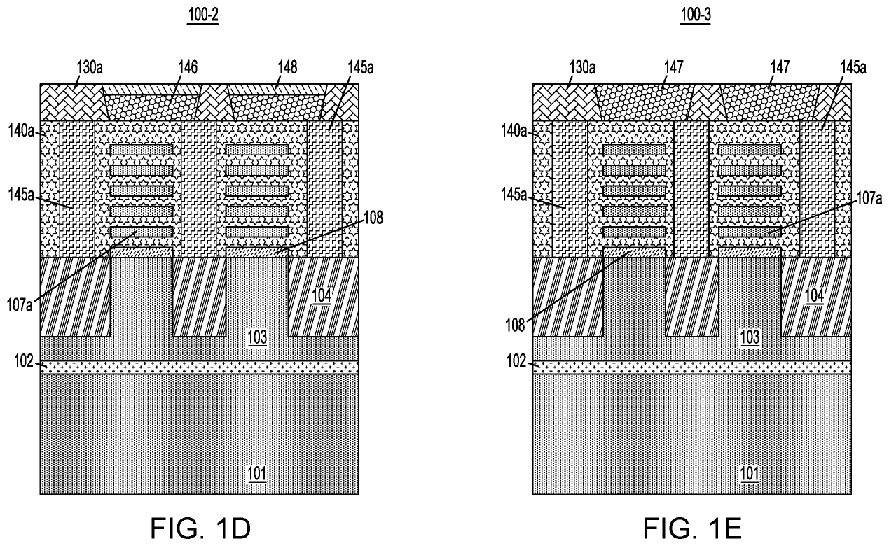

The cross-sectional views in FIGS. 1A, 1C, 2A, 2C, 4A, 4C, 5A, 5C, 7A, 7C, 9A, 9C, 10A and 10C are taken across gate structures (e.g., across gate widths) and illustrate gate widths and channel widths in the left-to-right directions. The cross-sectional views in FIGS. 1B, 1D, 1E, 2B, 3, 4B, 4D, 5B, 6, 7B, 8, 9B, 10B and 11-13 are taken along a gate structure (e.g., along a gate length) and illustrate gate lengths and channel lengths in the left-to-right directions.

FIGS. 1A and 1B depict a semiconductor structure 100 following formation of a bottom level of transistors and dielectric placeholder layers 143 for subsequently formed inter-gate contacts (also referred to herein as “conductive contacts”). FIG. 1C depicts a semiconductor structure 100-1 in an alternative embodiment to the semiconductor structure 100. In more detail, FIG. 1C depicts the semiconductor structure 100-1 following formation of a bottom level of transistors and SAC cap layers 144. In the semiconductor structure 100-1, instead of the dielectric placeholder layers 143, the SAC cap layers 144 function as placeholders for subsequently formed inter-gate contacts.

The semiconductor structure 100 and the semiconductor structure 100-1 each include a stacked structure of a plurality of lower transistors (also referred to herein as “first transistors”). The lower transistors include nanosheet transistors. For example, the lower transistors include a plurality of first channel layers 107a alternately stacked with and surrounded by first gate structures 140a. The lower transistors further include first source/drain regions 142a, which may be, for example, n-type and/or p-type source/drain regions. The embodiments are not necessarily limited to the shown number of first channel layers 107a, and there may be more or less layers in the same alternating configuration depending on design constraints with the first gate structures 140a.

A first semiconductor substrate 101 and a second semiconductor substrate 103 include semiconductor material including, but not limited to, silicon, III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101 between the first semiconductor substrate 101 and the second semiconductor substrate 103. In an illustrative embodiment, the etch stop layer 102 includes silicon germanium (SiGe) with, for example, a germanium concentration of about 30% (e.g., SiGe30) or SiO₂ and the first and second semiconductor substrates 101 and 103 include silicon.

According to one or more embodiments, the etch stop layer 102 is epitaxially grown on the first semiconductor substrate 101, the second semiconductor substrate 103 is epitaxially grown on the etch stop layer 102. The etch stop layer 102 functions as an etch stop when removing the first semiconductor substrate 101 in connection with backside contact processing and/or backside power rail formation. As used herein, “frontside refers to a side on top of the second semiconductor substrate 103 and/or in front of, on top of or in an upward direction from the stacked nanosheet/gate and channel layers of the transistors in the orientation shown in the cross-sectional figures. As used herein, “backside” refers to a side below the semiconductor substrate 103 and/or behind, under, below or in a downward direction from the stacked nanosheet/gate and channel layers of the transistors in the orientation shown in the cross-sectional figures (e.g., opposite the “frontside”).

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

A bottom dielectric layer 108 (e.g., bottom dielectric isolation (BDI) layer) is disposed between the second semiconductor substrate 103 and lowermost first gate structures 140a and first source/drain regions 142a. In an illustrative embodiment, the bottom dielectric layer 108 includes an oxide such as, for example, silicon dioxide (SiO₂).

Isolation regions 104 (e.g., shallow trench isolation (STI)) regions are formed between nanosheet stacks in recessed portions of the second semiconductor substrate 103. Isolation regions 104 including dielectric material fill in the recessed portions of the second semiconductor substrate 103. The dielectric material may include, for example, SiO₂, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

In the semiconductor structure 100, first gate spacers 112a are disposed on sides of the uppermost first gate structures 140a. In the semiconductor structure 100-1, extended gate spacers 112a′, which are similar to first gate spacers 112a, are disposed on sides of the uppermost first gate structures 140a, but extend beyond upper/top surfaces of the uppermost first gate structures 140a on sides of the SAC cap layers 144. The spacer material can include for example, one or more dielectrics, including, but not necessarily limited to, SiN, SiON, SiOC, SiCN, BN, SiBN, SiBCN, SiOCN, SiOₓ, and combinations thereof. The first gate spacers 112a and extended gate spacers 112a′ can be formed by any suitable technique such as deposition followed by directional etching. Deposition may include, but is not limited to, ALD or CVD. Directional etching may include but is not limited to, reactive ion etching (RIE).

First inner spacers 113a are disposed on sides of lower first gate structures 140a above and/or under end portions of the first channel layers 107a. The material of the first inner spacers 113 can include, but is not necessarily limited to, a nitride, such as, SiN, SiON, SiCN, BN, SiBN, SiBCN or SiOCN. In an illustrative embodiment, the first gate spacers 112a and extended gate spacers 112a′ are formed from the same or similar material to that of the first inner spacers 113a. Like the first gate spacers 112a and extended gate spacers 112a′, the first inner spacers 113a can be formed by any suitable techniques such as deposition followed by isotropic etching.

First source/drain regions 142a are epitaxially grown between the lower nanosheet stacks. The first source/drain regions 142a correspond to lower transistors. The first source/drain regions 142a include epitaxial layers grown from sides of the first channel layers 107a. Side surfaces of respective ones of the first channel layers 107a contact a side surface of at least one adjacent first source/drain region 142a. The top surfaces of the first source/drain regions 142a are above the top surfaces of uppermost ones of the first channel layers 107a for the lower transistors of a transistor stack.

According to a non-limiting embodiment of the present invention, the conditions of the epitaxial growth process for the first source/drain regions 142a are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the first source/drain regions 142a can include silicon doped with n-type dopants including, for example, phosphorus (P), arsenic (As) and antimony (Sb). In the case of p-type FETS (pFETs), the first source/drain regions 142a can include silicon doped with n-type dopants including, for example, boron (B), boron fluoride (BF₂), gallium (Ga), indium (In), and thallium (Tl).

In the semiconductor structure 100, a first inter-layer dielectric (ILD) layer 130a is deposited to fill in portions on and around the first source/drain regions 142a, and on top of first gate structures 140a. In the semiconductor structure 100-1, another first ILD layer 130a′ is deposited to fill in portions on and around the first source/drain regions 142a, and on top of first gate structures 140a where the extended gate spacers 112a′ and SAC cap layers 144 are not formed. The first ILD layer 130a and other first ILD layer 130a′ are deposited using deposition techniques such as, for example, CVD, PECVD, RFCVD, PVD, ALD, MBD, PLD, and/or LSMCD, followed by a planarization process, such as, chemical mechanical planarization (CMP). The first ILD layer 130a and other first ILD layer 130a′ may include, for example, SiOₓ, SiOC, SiOCN or some other dielectric.

The first gate structures 140a, include, for example, gate portions (also referred to herein as “gate regions”) and dielectric portions. In illustrative embodiments, each first gate structure 140a includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate portion of the each first gate structure 140a includes a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Portions of the first gate structures 140a are removed where gate isolation regions (also referred to herein as “gate cut portions”) are to be formed. Referring to FIG. 1B, first gate isolation regions 145a are formed through portions of the first gate structures 140a over isolation regions 104.

The first gate isolation regions 145a respectively include a dielectric layer including, for example, a nitride material (e.g., SiN, SiON, SiCN, BN, SiBN, SiBCN and/or SiOCN). The dielectric material of the first gate isolation regions 145a is deposited using deposition techniques such as, for example, CVD, PECVD, RFCVD, PVD, ALD, MBD, PLD, and/or LSMCD, followed by a planarization process, such as, CMP. Although not shown, the semiconductor structure 100-1 also includes the first gate isolation regions 145a.

In the semiconductor structure 100, a plurality of dielectric placeholder layers 143, which are placeholders for subsequently formed inter-gate contacts, are formed in the first ILD layer 130a over the uppermost first gate structures 140a. The dielectric placeholder layers 143 are formed on metal gate portions (e.g., gate regions) on top surfaces of the first gate structures 140a. In illustrative embodiments, a width of respective ones of the dielectric placeholder layers 143 (e.g., in left-right direction in FIG. 1A) is less than a gate width (e.g., also in left-right direction in FIG. 1A) of the first gate structures 140a. As can be seen in FIG. 1B, respective ones of the dielectric placeholder layers 143 overlap at least part of the channel length (e.g., in left-right direction in FIG. 1B) of the first channel layers 107a. A material of the dielectric placeholder layers 143 includes, for example, nitride-based materials such as, for example, SiN, which can be selectively removed with respect to the first ILD layer 130a. The dielectric placeholder layers 143 are formed by removing portions of the first ILD layer 130a to form trenches in the first ILD layer 130a, and depositing the dielectric material of the dielectric placeholder layers 143 in the trenches using one or more deposition techniques such as, for example, CVD, PECVD, RFCVD, PVD, ALD, MBD, PLD, and/or LSMCD, followed by a planarization process, such as, CMP.

In the semiconductor structure 100-1, instead of the dielectric placeholder layers 143 of the semiconductor structure 100, the SAC cap layers 144 function as the placeholders for subsequently formed inter-gate contacts. The SAC cap layers 144 include, but are not necessarily limited to, silicon, SiN, SiBN, SiOCN, amorphous carbon or oxides. According to an embodiment of the present invention, the SAC cap layers 144 are deposited on top surfaces of the uppermost first gate structures 140a using, for example, deposition techniques including, but not limited to, CVD, PECVD, RFCVD, PVD, ALD, MLD, MBD, PLD, LSMCD, sputtering, and/or plating, followed by a planarization process, such as, for example, CMP. The SAC cap layers 144 are formed between the extended gate spacers 112a′.

In another alternative embodiment, FIG. 1D depicts a semiconductor structure 100-2 similar to the semiconductor structure 100. However, unlike the dielectric placeholder layers 143 of the semiconductor structure 100, the placeholders for inter-gate contacts in the semiconductor structure 100-2 include a metal portion 146 and a dielectric portion 148. In yet another alternative embodiment, FIG. 1E depicts a semiconductor structure 100-3 similar to the semiconductor structure 100. However, unlike the semiconductor structure 100, dielectric placeholder layers 143 are not used and, instead, inter-gate contacts 147 are formed outright without using placeholders. Similar to the process for forming the dielectric placeholder layers 143 in the semiconductor structure 100, the placeholders including the metal portion 146 and dielectric portion 148 in the semiconductor structure 100-2, and the inter-gate contacts 147 in the semiconductor structure 100-3 are formed by removing portions of the first ILD layer 130a to form trenches in the first ILD layer 130a. In the case of the placeholders including the metal portion 146 and dielectric portion 148 in the semiconductor structure 100-2, a metal layer is deposited to fill a portion of a trench to form a metal portion 146, then a remaining portion of the trench is filled with dielectric layer to form the dielectric portion 148, followed by a CMP process. In the case of the inter-gate contacts 147 in the semiconductor structure 100-3, metal is deposited to fill the trenches, followed by a CMP process. The deposition of the dielectric and metal material in the trenches is performed using one or more deposition techniques such as, for example, CVD, PECVD, RFCVD, PVD, ALD, MBD, PLD, and/or LSMCD. The dielectric portion 148 may include the same or a similar material to that of the dielectric placeholder layers 143, and the material of the metal portion 146 and inter-gate contacts 147 includes, for example, tungsten, cobalt, zirconium, tantalum, titanium, aluminum, ruthenium, and/or copper.

Similar to the location of the dielectric placeholder layers 143 in the semiconductor structure 100, the placeholders including the metal portion 146 and dielectric portion 148 in the semiconductor structure 100-2, and the inter-gate contacts 147 in the semiconductor structure 100-3 are formed in the first ILD layer 130a over the uppermost first gate structures 140a. The placeholders including the metal portion 146 and dielectric portion 148, and the inter-gate contacts 147 are formed on metal gate portions (e.g., gate regions) on top surfaces of the first gate structures 140a. In illustrative embodiments, a width of respective ones of the placeholders including the metal portion 146 and dielectric portion 148, and of the inter-gate contacts 147 (e.g., in left-right direction in FIG. 1A) is less than a gate width (e.g., also in left-right direction in FIG. 1A) of the first gate structures 140a. Respective ones of the placeholders including the metal portion 146 and dielectric portion 148, and of the inter-gate contacts 147, overlap at least part of the channel length (e.g., in left-right direction in FIGS. 1D and 1E) of the first channel layers 107a.

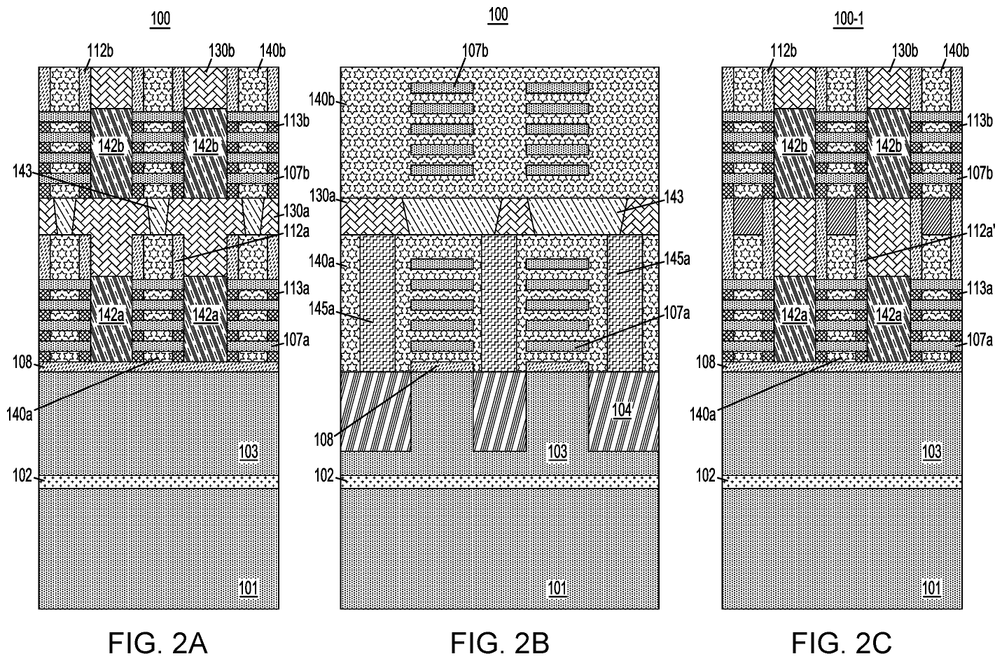

Referring to FIGS. 2A-2C upper transistors similar to the lower transistors are formed on the structures of FIGS. 1A-C. In more detail, in the semiconductor structures 100 and 100-1, a plurality of upper transistors (also referred to herein as “second transistors”). The upper transistors include nanosheet transistors. For example, the upper transistors include a plurality of second channel layers 107b alternately stacked with and surrounded by second gate structures 140b. The upper transistors further include second source/drain regions 142b, which may be, for example, n-type and/or p-type source/drain regions. The embodiments are not necessarily limited to the shown number of second channel layers 107b, and there may be more or less layers in the same alternating configuration depending on design constraints with the second gate structures 140b.

Second gate spacers 112b are disposed on sides of the uppermost second gate structures 140b. Second inner spacers 113b are disposed on sides of lower second gate structures 140b above and/or under end portions of the second channel layers 107b. The materials of the second gate spacers 112b and second inner spacers 113b can be the same or similar material as that of the first gate spacers 112a and first inner spacers 113a, and can be deposited using the same or similar techniques as those used for the first gate spacers 112a and first inner spacers 113a.

Second source/drain regions 142b are epitaxially grown between the upper nanosheet stacks. The second source/drain regions 142b correspond to upper transistors. The second source/drain regions 142b include epitaxial layers grown from sides of the second channel layers 107b. Side surfaces of respective ones of the second channel layers 107b contact a side surface of at least one adjacent second source/drain region 142b. The top surfaces of the second source/drain regions 142b are above the top surfaces of uppermost ones of the second channel layers 107b for the upper transistors of a transistor stack.

According to a non-limiting embodiment of the present invention, the conditions of the epitaxial growth process for the second source/drain regions 142b is the same or similar as those for the first source/drain regions 142a. In the case of n-type FETS (nFETs), the second source/drain regions 142b can include silicon doped with n-type dopants including, for example, phosphorus (P), arsenic (As) and antimony (Sb). In the case of p-type FETS (pFETs), the second source/drain regions 142b can include silicon doped with n-type dopants including, for example, boron (B), boron fluoride (BF₂), gallium (Ga), indium (In), and thallium (Tl).

In the semiconductor structures 100 and 100-1, a second ILD layer 130b is deposited to fill in portions on and around the second source/drain regions 142b. The second ILD layer 130b is deposited using deposition techniques such as, for example, CVD, PECVD, RFCVD, PVD, ALD, MBD, PLD, and/or LSMCD, followed by a planarization process, such as, CMP. The second ILD layer 130b may include, for example, SiOₓ, SiOC, SiOCN or some other dielectric.

The second gate structures 140b, include, for example, gate portions (also referred to herein as “gate regions”) and dielectric portions. In illustrative embodiments, each second gate structure 140b includes a gate dielectric layer such as, for example, a high-K dielectric layer including the same or similar materials as those of the gate dielectric layers for the first gate structures 140a. According to an embodiment, like the first gate structures 140a, the gate portion of each second gate structure 140b includes a metal gate portion including a WFM layer, which can be deposited on the gate dielectric layer, and a gate metal layer deposited on the WFM layer and the gate dielectric layer. The WFM and gate metal layers of the second gate structures 140b include the same or similar materials as those of the WFM and gate metal layers of the first gate structures 140a.

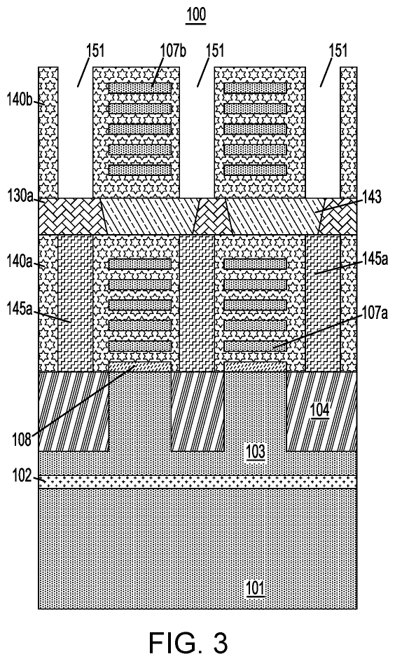

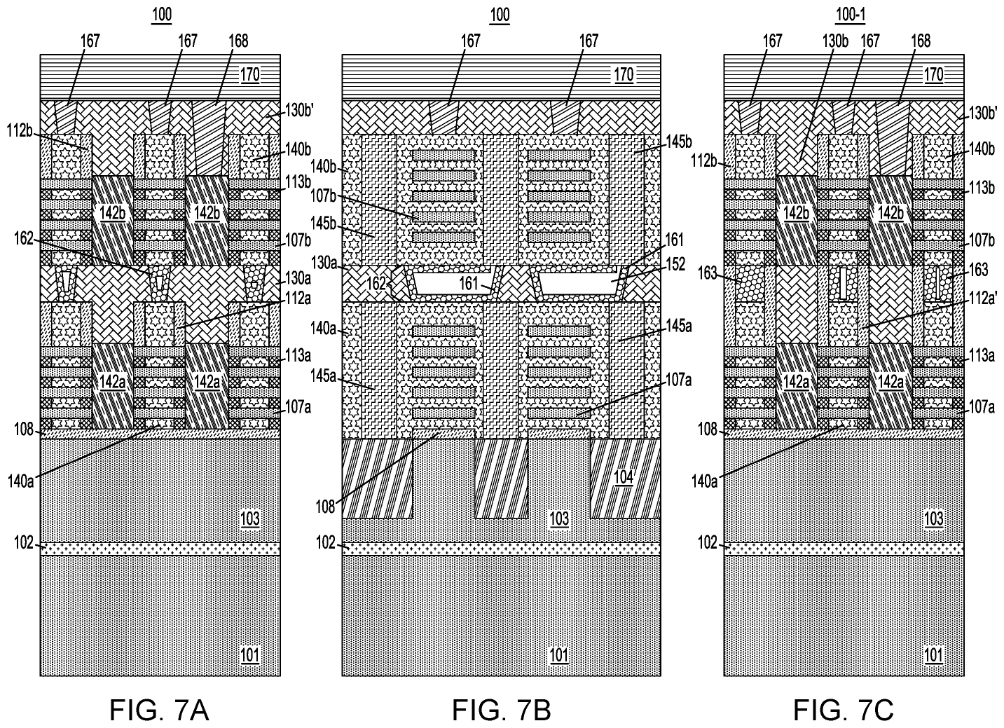

Referring to FIG. 3, portions of the second gate structures 140b are removed in locations corresponding to where the first gate isolation regions 145a are formed. The removal of the portions of the second gate structures 140b creates openings 151 exposing portions of the first ILD layer 130a and portions of the dielectric placeholder layers 143. The openings are formed in locations where second gate isolation regions 145b will be formed (see, e.g., FIG. 7B). Although not shown, in the case of semiconductor structure 100-1, the openings 151 expose the SAC cap layers 144. Although not shown, in the case of semiconductor structure 100-2, the openings expose portions of the first ILD layer 130a and parts of the dielectric portions 148. Although not shown, in the case of semiconductor structure 100-3, the openings expose portions of the first ILD layer 130a and parts of the inter-gate contacts 147. The removal of the portions of the second gate structures 140b is performed using, for example, anisotropic etching (e.g., RIE).

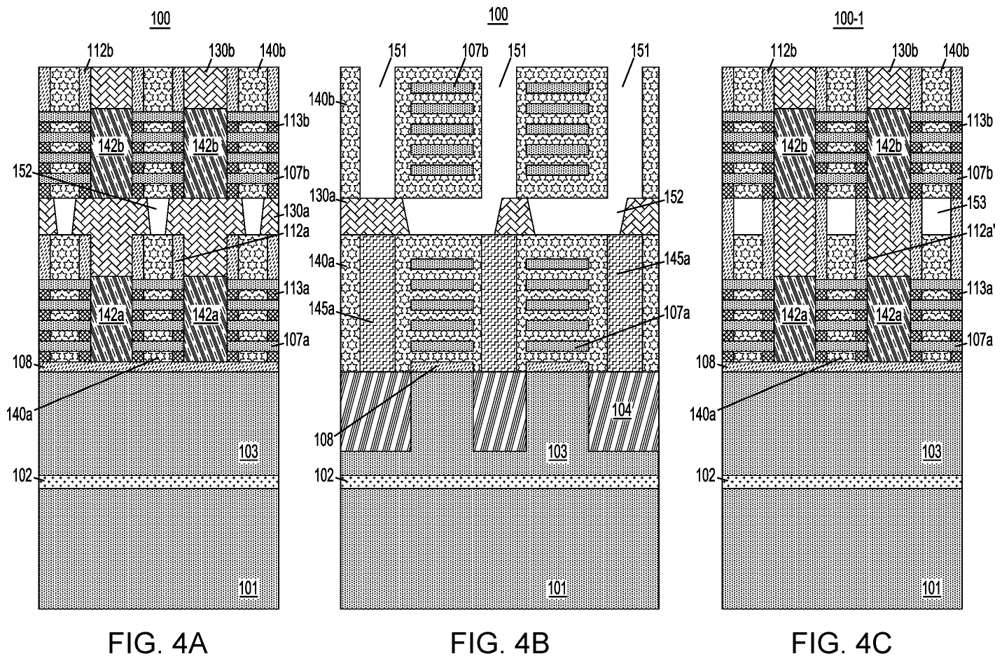

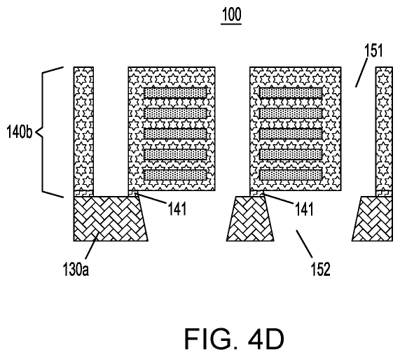

Referring to FIGS. 4A-4D, the dielectric placeholder layers 143 and SAC cap layers 144 exposed by the openings 151 are selectively removed with respect to the materials of the first ILD layer 130a, extended gate spacers 112a′ and first and second gate structures 140a and 140b. The removal of the dielectric placeholder layers 143 creates cavities 152 and the removal of the SAC cap layers 144 creates cavities 153. FIG. 4D depicts a gate dielectric layer portion 141 of the second gate structures 140b (e.g., high-K dielectric layer), which is not shown in FIG. 4B. FIG. 4D is included to illustrate that in the semiconductor structure 100 exposed parts of the gate dielectric layer 141 are also selectively removed with respect to the materials of the first ILD layer 130a, extended gate spacers 112a′ and first and second gate structures 140a and 140b to create the cavities 152. As can be seen in FIGS. 4A-4D, the cavities 152 and 153 leave exposed bottom surfaces of second gate structures 140b including corresponding gate regions and top surfaces of the first gate structures 140a including corresponding gate regions.

In the case of the semiconductor structure 100-2, although not shown in the figures, the dielectric portions 148 are selectively removed with respect to the materials of the first ILD layer 130a, second gate structures 140b and underlying metal portions 146. The selective removal of the dielectric placeholder layers 143, SAC cap layers 144 and dielectric portions 148 is performed using, for example, a selective wet etch process. In the case of the semiconductor structure 100-3, a removal process is not performed since the inter-gate contacts 147 are already formed and there is no placeholder.

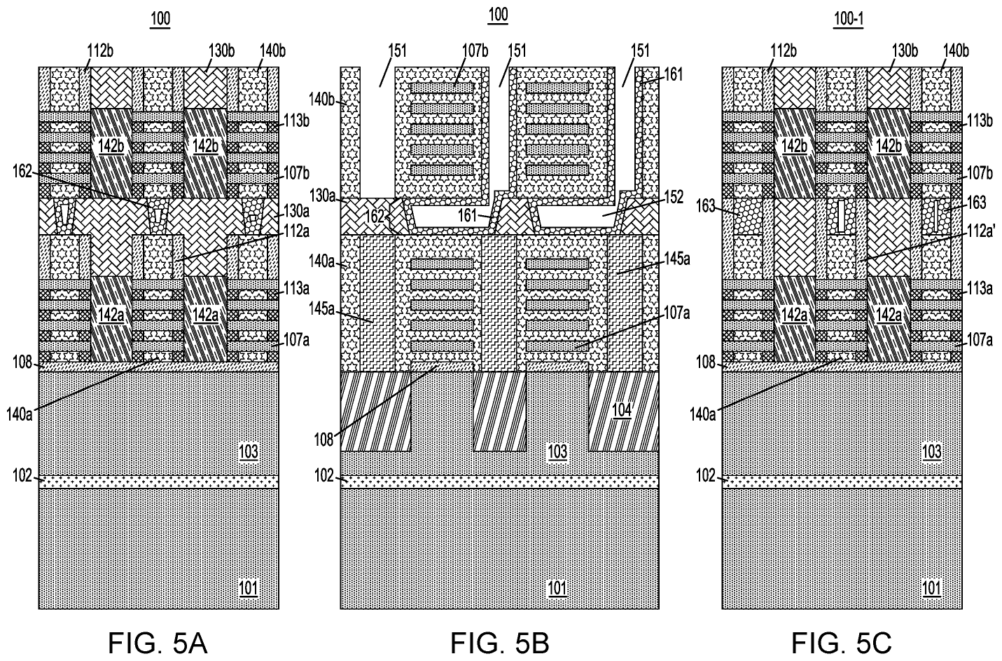

Referring to FIGS. 5A-5C, metal liner layers 161 are conformally deposited in the openings 151 corresponding to the cavities 152 and 153 and in the cavities 152 and 153 to form conductive contacts 162 and 163 (also referred to herein as “inter-gate contacts”). The metal liner layers 161 line the side and bottom surfaces of the openings 151 and of the cavities 152 and 153. As shown in different examples of the conductive contacts 162 and 163 in FIGS. 5A and 5B, depending on the sizes of the cavities 152 and 153, in some instances, the metal liner layers 161 forming the conductive contacts 162 or 163 may meet (e.g., “pinch-off” or “plug”) or come close to meeting in a given direction. Different examples of levels of pinching-off for the conductive contacts 162 and 163 are shown in FIGS. 5A and 5C. The metal liner layers 161 are deposited using, for example, a conformal deposition technique such as, but not necessarily limited to, ALD. The metal liner layers 161 include, for example, conductive metal material such as, but not necessarily limited to, tungsten, cobalt, zirconium, tantalum, titanium, aluminum, ruthenium, and/or copper.

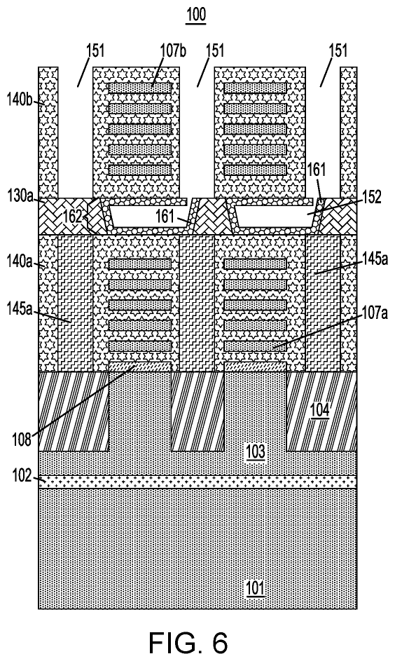

Referring to FIG. 6, in an illustrative embodiment, the metal liner layers 161 are removed from the openings 151 where the second gate isolation regions 145b (e.g., gate cut portions) are to be formed, leaving the metal liner layers 161 in the cavities 152 and 153 to form the conductive contacts 162 and 163 disposed between and contacting the gate regions of the first and second gate structures 140a and 140b.

In illustrative embodiments, the conductive contacts 162 and 163 include the metal liner layers 161 around a vacant area (e.g., unfilled portion of the cavities 152 or 153) between a top surface of a first gate structure 140a including a corresponding gate region and a bottom surface of a second gate structure 140b including a corresponding gate region. As can be seen, the bottom surface of the second gate structure 140b is disposed opposite the top surface of the first gate structure 140a.

The conductive contacts 162 are formed in the first ILD layer 130a over the uppermost first gate structures 140a and the conductive contacts 163 are formed in the other first ILD layer 130a′ over the uppermost first gate structures 140a. The conductive contacts 162 and 163 are formed on and contact metal gate portions (e.g., gate regions) on top surfaces of the first gate structures 140a, and are formed under and contact metal gate portions (e.g., gate regions) on bottom surfaces of the second gate structures 140b. In illustrative embodiments, a width of respective ones of the conductive contacts 162 and 163 (e.g., in left-right direction in FIGS. 5A and 5C) is less than a gate width (e.g., also in left-right direction in FIGS. 5A and 5C) of the first gate structures 140a and the second gate structures 140b. As can be seen in FIGS. 5B and 6, respective ones of the conductive contacts 162 overlap at least part of the channel length (e.g., in left-right direction in FIGS. 5B and 6) of the first and second channel layers 107a and 107b. Although not shown, respective ones of the conductive contacts 163 also overlap at least part of the channel length of the first and second channel layers 107a and 107b. In connection with the semiconductor structure 100-2 from FIG. 1D, although not shown in the figures, the metal liner layers 161 are deposited on surfaces of the vacant area left by the removal of the dielectric portions 148 and on the exposed surface of the metal portion 146. In some cases, the metal liner layers 161 may be pinched-off and fill in the vacant area left by the removal of the dielectric portions 148.

Referring to FIGS. 7A-7C, subsequent processing to form the second gate isolation regions 145b, frontside gate contacts 167, frontside source/drain contacts 168 and back-end-of-line (BEOL) interconnects 170 is performed. In more detail, dielectric material is deposited in the openings 151 to form the second gate isolation regions 145b (e.g., gate cut portions). The second gate isolation regions 145b respectively include a dielectric layer including, for example, a nitride material (e.g., SiN, SiON, SiCN, BN, SiBN, SiBCN and/or SiOCN). The dielectric material of the second gate isolation regions 145b is deposited using deposition techniques such as, for example, CVD, PECVD, RFCVD, PVD, ALD, MBD, PLD, and/or LSMCD, followed by a planarization process, such as, CMP. Although not shown, the semiconductor structure 100-1 also includes the second gate isolation regions 145b.

Additional ILD material is deposited to form a third ILD layer 130b′ on top of the second ILD layer 130b and the second gate structures 140b. Then, frontside gate contacts 167 and frontside source/drain contacts 168 are formed in the second and/or third ILD layers 130b and 130b′. In forming the frontside gate and source/drain contacts 167 and 168, openings are formed through portions of the second and/or third ILD layers 130b and 130b′. The openings expose portions of the second gate structures 140b on which the frontside gate contacts 167 are to be formed and portions of the second source/drain regions 142b on which the frontside source/drain contacts 168 are to be formed. According to an embodiment, masks are formed on parts of the third ILD layer 130b′ and exposed portions of the second and third ILD layers 130b and 130b′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers including the same or similar materials as those used for the conductive contacts 162 and 163 are deposited in the openings to form the frontside gate and source/drain contacts 167 and 168. The metal layers can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the third ILD layer 130b′.

The frontside source/drain contacts 168 extend through the second and third ILD layers 130b and 130b′ to land on and contact the corresponding second source/drain regions 142b. The frontside gate contacts 167 extend through the third ILD layer 130b′ to land on and contact the corresponding second gate structures 140b. Frontside BEOL interconnects 170 are formed on the third ILD layer 130b′ and are connected to the frontside gate and source/drain contacts 167 and 168 through a plurality of wires.

As can be understood, by virtue of the conductive contacts, gate voltages can be delivered to the first gate structures 140a through the frontside gate contacts 167 and the second gate structures 140b.

Connections to the first source/drain regions 142a can be made from a backside power delivery network (BSPDN) formed following semiconductor structure flipping, removal of the first semiconductor substrate 101, etch stop layer 102 and all or part of second semiconductor substrate 103, and replacement with a backside ILD layer, and backside source/drain contacts to connect to the BSPDN.

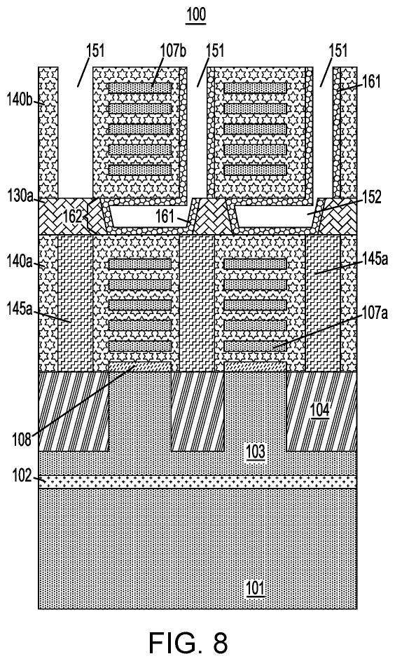

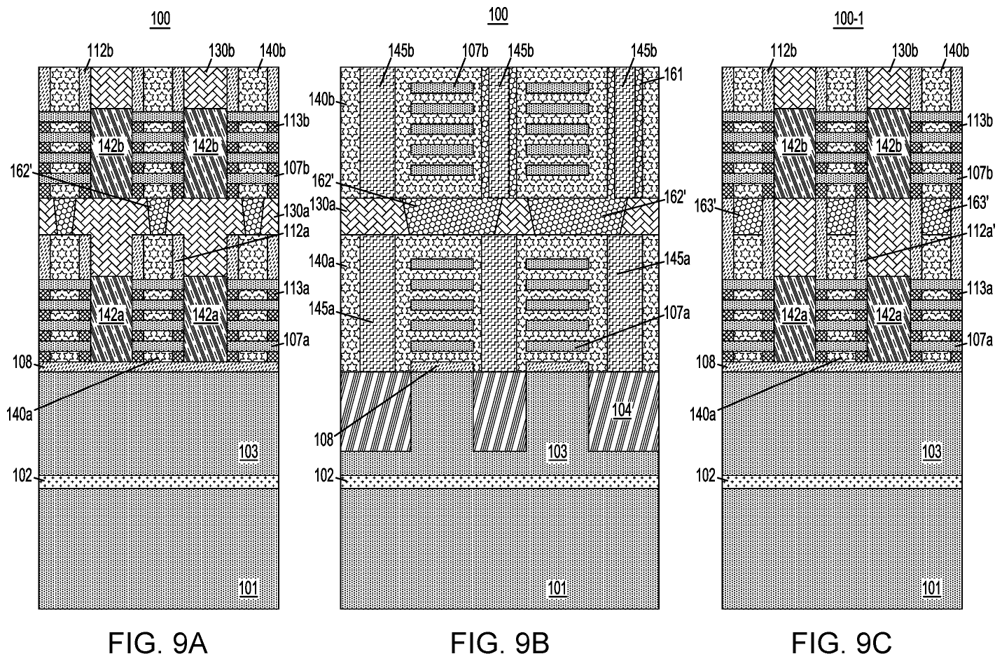

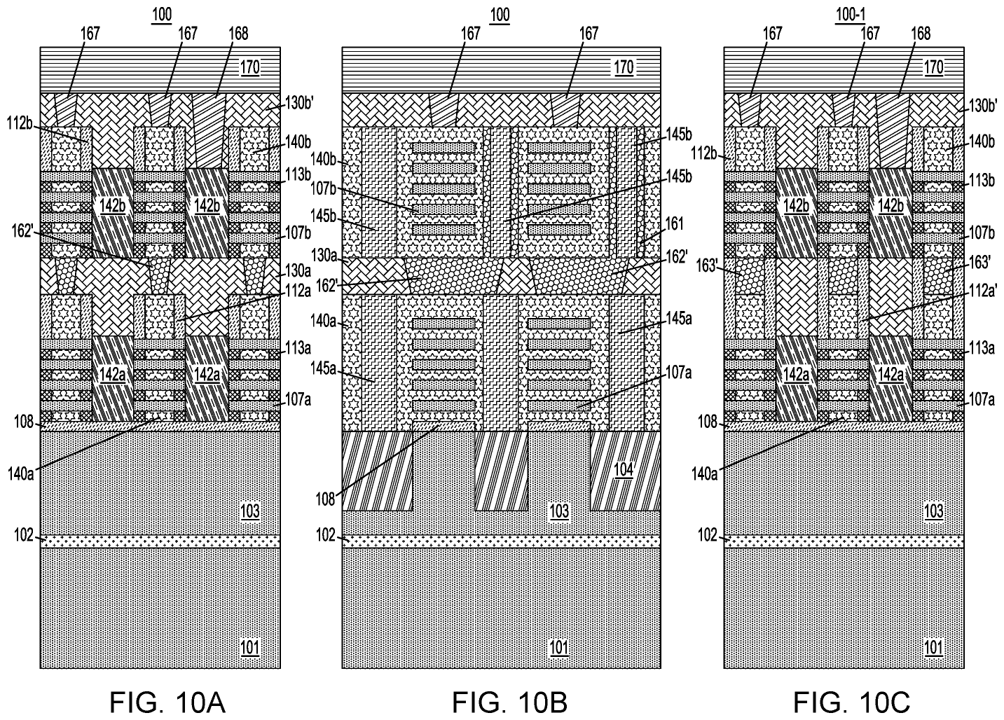

In an alternative embodiment to what is shown in FIG. 6, following processing from FIGS. 5C, instead of removing the metal liner layers 161 from each of the surfaces in the openings 151, FIG. 8 depicts limited removal of a portion of the metal liner layer 161 from bottom parts of the openings 151. The targeted removal can be performed using, for example, a RIE process. Referring to FIGS. 9A-9C, following the targeted removal of the portions of the metal liner layer 161, further metal deposition is performed to form conductive contacts 162′ and 163′. In illustrative embodiments, the conductive contacts 162′ and 163′ fill in the cavities 152 and 153. The conductive contacts 162′ and 163′ are connected to the remaining portions of the metal liner layers 161 formed on respective sides of adjacent second gate structures 140b. Remaining portions of the openings 151 are filled with dielectric material in a similar manner to that discussed in connection with FIGS. 7A-7C to form second gate isolation regions 145b. Respective ones of the remaining portions of the metal liner layers 161 are disposed between a second gate structure 140b and a second gate isolation region 145b. In the embodiment shown in FIG. 9B, portions of metal liner layers 161 disposed on opposite sides of a second gate isolation region 145b are electrically isolated from each other. As can be seen in FIG. 9B, one or more of the second gate isolation regions 145b may not include metal liner layers 161 or a conductive contact 162′ or 163′ disposed below the second gate isolation region 145b.

Referring to FIGS. 10A-10C, subsequent processing to form the frontside gate contacts 167, frontside source/drain contacts 168 and frontside BEOL interconnects 170 is performed in the same or similar manner as described in connection with FIGS. 7A-7C. The conductive contacts 162′ are formed in the first ILD layer 130a over the uppermost first gate structures 140a and the conductive contacts 163′ are formed in the other first ILD layer 130a′ over the uppermost first gate structures 140a. The conductive contacts 162′ and 163′ are formed on and contact metal gate portions (e.g., gate regions) on top surfaces of the first gate structures 140a, and are formed under and contact metal gate portions (e.g., gate regions) on bottom surfaces of the second gate structures 140b. In illustrative embodiments, a width of respective ones of the conductive contacts 162′ and 163′ (e.g., in left-right direction in FIGS. 10A and 10C) is less than a gate width (e.g., also in left-right direction in FIGS. 10A and 10C) of the first gate structures 140a and the second gate structures 140b. As can be seen in FIG. 10B, respective ones of the conductive contacts 162′ overlap at least part of the channel length (e.g., in left-right direction in FIG. 10B) of the first and second channel layers 107a and 107b. Although not shown, respective ones of the conductive contacts 163′ also overlap at least part of the channel length of the first and second channel layers 107a and 107b.

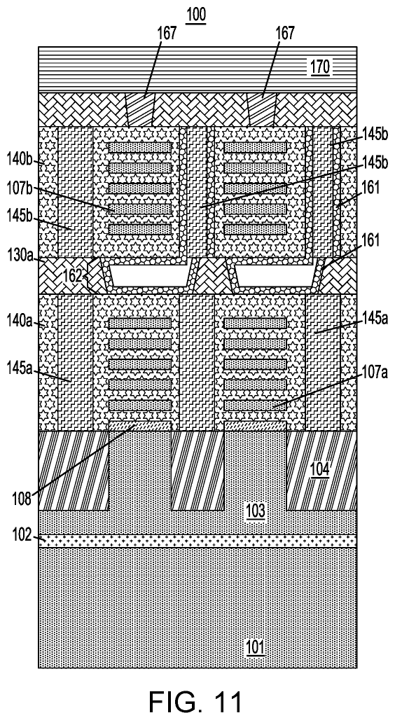

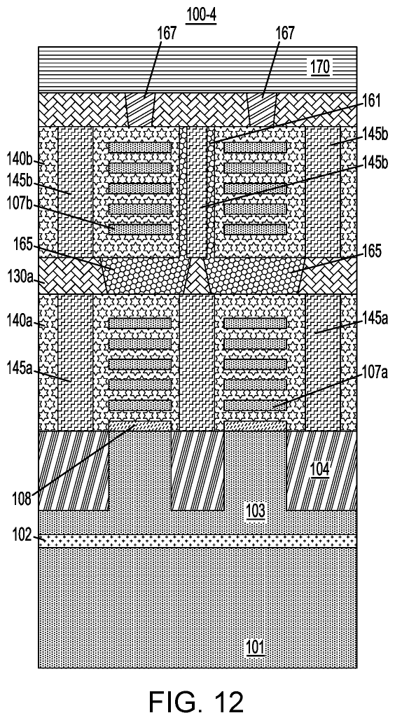

FIG. 11 depicts a cross-sectional view of an alternate embodiment to what is shown in FIG. 10B, where the metal of a conductive contact 162 does not completely fill a cavity 152, similar to the embodiment in FIG. 7B. Unlike what is shown in FIG. 7B, and similar to what is shown in FIG. 10B, the conductive contacts 162 in FIG. 11 are connected to the remaining portions of the metal liner layers 161 formed on respective sides of adjacent second gate structures 140b. Respective ones of the remaining portions of the metal liner layers 161 are disposed between a second gate structure 140b and a second gate isolation region 145b. Like the embodiment shown in FIG. 10B, in FIG. 11, portions of metal liner layers 161 disposed on opposite sides of a second gate isolation region 145b are electrically isolated from each other.

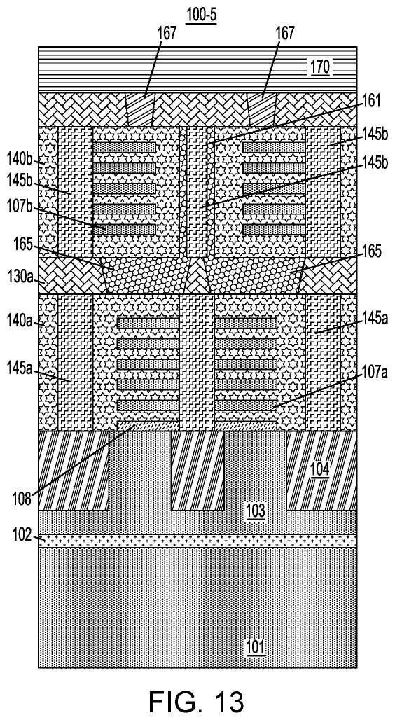

FIG. 12 depicts a cross-sectional view of a semiconductor structure 100-4 of another alternative embodiment taken along a gate structure where inter-gate contacts are formed through metal deposition through the same gate cut portion instead of different gate cut portions as in the semiconductor structure 100. In more detail, as can be seen in FIG. 12, the conductive contacts 165 fill in cavities (e.g., cavities 152). The conductive contacts 165 are respectively connected to portions of metal liner layers 161 formed on respective sides of adjacent second gate structures 140b and on opposite sides (e.g., left and right sides in FIG. 12) of the same second gate isolation region 145b. A remaining portion of what was opening 151 is filled with dielectric material in a similar manner to that discussed in connection with FIGS. 7A-7C to form the second gate isolation region 145b. As can be seen in FIG. 12, the two other second gate isolation regions 145b do not include metal liner layers 161 or a conductive contact 165 disposed below the second gate isolation regions 145b. The metal liner layers 161 in FIG. 12 are disposed between a second gate structure 140b and the same second gate isolation region 145b. In the embodiment shown in FIG. 12, the portions of metal liner layers 161 disposed on opposite sides of the second gate isolation region 145b are electrically isolated from each other.

Referring to FIG. 12, subsequent processing to form the frontside gate contacts 167, frontside source/drain contacts and frontside BEOL interconnects 170 is performed in the same or similar manner as described in connection with FIGS. 7A-7C. The conductive contacts 165 are formed in the first ILD layer 130a over the uppermost first gate structures 140a. The conductive contacts 165 are formed on and contact metal gate portions (e.g., gate regions) on top surfaces of the first gate structures 140a, and are formed under and contact metal gate portions (e.g., gate regions) on bottom surfaces of the second gate structures 140b. In illustrative embodiments, a width of respective ones of the conductive contacts 165 is less than a gate width of the first gate structures 140a and the second gate structures 140b. As can be seen in FIG. 12, respective ones of the conductive contacts 165 overlap at least part of the channel length (e.g., in left-right direction in FIG. 10B) of the first and second channel layers 107a and 107b.

FIG. 13 depicts a cross-sectional view of an alternate embodiment to what is shown in FIG. 12, where, unlike the semiconductor structure 100-4, the transistors in the semiconductor structure 100-5 include forksheet transistors. In more detail, in the semiconductor structure 100-5 in FIG. 13, in illustrative embodiments, the first gate isolation regions 145a and second gate isolation regions 145b respectively contact sidewalls of first channel layers 107a and second channel layers 107b to form forksheet transistors. In a forksheet FET, an nFET and a pFET are integrated in the same structure, where a dielectric layer separates the nFET and pFET. As can be seen in FIG. 13, the first channel layers 107a and the second channel layers 107b respectively contact the first gate isolation regions 145a and second gate isolation regions 145b where the portions of metal layers 161 are not present.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide structures for and techniques for forming inter-gate contacts for stacked FETs. In sequential integration of FETs, top and bottom gates are not intrinsically electrically connected. Advantageously, the illustrative embodiments provide a solution for electrically connecting top and bottom gates, which avoids complex backside gate connections and/or additional metal routing congestion. The illustrative embodiments provide structures for and methods to form inter-gate conductive contacts connecting a top surface of a bottom gate to a bottom surface of a top gate.

In one embodiment, a semiconductor device includes a first transistor including a first gate region, and a second transistor including a second gate region, wherein the second transistor is stacked over the first transistor. A conductive contact is disposed between and contacts a surface of the first gate region and a surface of the second gate region, wherein the surface of the second gate region is disposed opposite the surface of the first gate region.

The first transistor may include a first plurality of stacked channel layers, and the second transistor may include a second plurality of stacked channel layers. The conductive contact may overlap at least part of the first plurality of stacked channel layers and at least part of the second plurality of stacked channel layers.

The conductive contact can be connected to a conductive liner layer disposed on a side surface of the second gate region. The conductive liner layer may be disposed between the side surface of the second gate region and a side surface of a gate isolation region. An additional conductive liner layer may be disposed on an additional side surface of the gate isolation region and on a side surface of third gate region adjacent the second gate region. The additional conductive liner layer can be electrically isolated from the conductive liner layer and the additional side surface of the gate isolation region can be located opposite the side surface of the gate isolation region. The additional conductive liner layer can be connected to an additional conductive contact, wherein the additional conductive contact is disposed between the third gate region and a fourth gate region disposed under the third gate region.

The conductive contact can be formed around a vacant area between the surface of the first gate region and the surface of the second gate region. A width of the conductive contact can be less than a width of the first gate region and a width of the second gate region. The conductive contact may be self-aligned with at least the first gate region.

The semiconductor device may further include a dielectric layer between the surface of the first gate region and the surface of the second gate region, wherein the conductive contact is disposed through the dielectric layer. The first and the second transistors may include nanosheet transistors. The first and the second transistors may include forksheet transistors.

In sequential integration of FETs, top and bottom gates are not intrinsically electrically connected. Advantageously, the illustrative embodiments provide a solution for electrically connecting top and bottom gates, which avoids complex backside gate connections and/or additional metal routing congestion. The illustrative embodiments provide structures for and methods to form inter-gate conductive contacts connecting a top surface of a bottom gate to a bottom surface of a top gate.

In another embodiment, a semiconductor device includes a first gate region, a second gate region stacked over the first gate region, and a dielectric layer disposed between the first gate region and the second gate region. A conductive contact is disposed in the dielectric layer between the first gate region and the second gate region, wherein the conductive contact contacts the first gate region and the second gate region.

The conductive contact may overlap a channel layer of at least one of the first gate region and the second gate region. The conductive contact may be connected to a conductive liner layer disposed on a side surface of the second gate region. The conductive liner layer may be disposed between the side surface of the second gate region and a side surface of a gate isolation region.

The conductive contact may be formed around a vacant area between the first gate region and the second gate region.

In another embodiment, a semiconductor device includes a first nanosheet transistor including a first gate region, and a second nanosheet transistor including a second gate region, wherein the second nanosheet transistor is stacked over the first nanosheet transistor. A conductive contact is disposed between the first nanosheet transistor and the second nanosheet transistor. The conductive contact contacts a surface of the first gate region and a surface of the second gate region, wherein the surface of the second gate region is disposed opposite the surface of the first gate region.

The conductive contact may be disposed between a channel layer of the first nanosheet transistor and a channel layer of the second nanosheet transistor.

These and other features and advantages of embodiments described herein will become more apparent from the accompanying drawings and the following detailed description.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor comprising a first gate region;
a second transistor comprising a second gate region, wherein the second transistor is stacked over the first transistor; and
a conductive contact disposed between and contacting a surface of the first gate region and a surface of the second gate region, wherein the surface of the second gate region is disposed opposite the surface of the first gate region.

2. The semiconductor device of claim 1, wherein:
the first transistor comprises a first plurality of stacked channel layers;
the second transistor comprises a second plurality of stacked channel layers;
the conductive contact overlaps at least part of the first plurality of stacked channel layers and at least part of the second plurality of stacked channel layers.

3. The semiconductor device of claim 1, wherein the conductive contact is connected to a conductive liner layer disposed on a side surface of the second gate region.

4. The semiconductor device of claim 3, wherein the conductive liner layer is disposed between the side surface of the second gate region and a side surface of a gate isolation region.

5. The semiconductor device of claim 4, further comprising an additional conductive liner layer disposed on an additional side surface of the gate isolation region and on a side surface of third gate region adjacent the second gate region.

6. The semiconductor device of claim 5, wherein the additional conductive liner layer is electrically isolated from the conductive liner layer and the additional side surface of the gate isolation region is located opposite the side surface of the gate isolation region.

7. The semiconductor device of claim 5, wherein the additional conductive liner layer is connected to an additional conductive contact, wherein the additional conductive contact is disposed between the third gate region and a fourth gate region disposed under the third gate region.

8. The semiconductor device of claim 1, wherein the conductive contact is formed around a vacant area between the surface of the first gate region and the surface of the second gate region.

9. The semiconductor device of claim 1, wherein a width of the conductive contact is less than a width of the first gate region and a width of the second gate region.

10. The semiconductor device of claim 1, wherein the conductive contact is self-aligned with at least the first gate region.

11. The semiconductor device of claim 1, further comprising a dielectric layer between the surface of the first gate region and the surface of the second gate region, wherein the conductive contact is disposed through the dielectric layer.

12. The semiconductor device of claim 1, wherein the first and the second transistors comprise nanosheet transistors.

13. The semiconductor device of claim 1, wherein the first and the second transistors comprise forksheet transistors.

14. A semiconductor device comprising:
a first gate region;
a second gate region stacked over the first gate region;
a dielectric layer disposed between the first gate region and the second gate region; and
a conductive contact disposed in the dielectric layer between the first gate region and the second gate region, wherein the conductive contact contacts the first gate region and the second gate region.

15. The semiconductor device of claim 14, wherein the conductive contact overlaps a channel layer of at least one of the first gate region and the second gate region.

16. The semiconductor device of claim 14, wherein the conductive contact is connected to a conductive liner layer disposed on a side surface of the second gate region.

17. The semiconductor device of claim 16, wherein the conductive liner layer is disposed between the side surface of the second gate region and a side surface of a gate isolation region.

18. The semiconductor device of claim 14, wherein the conductive contact is formed around a vacant area between the first gate region and the second gate region.

19. A semiconductor device comprising:
a first nanosheet transistor comprising a first gate region;
a second nanosheet transistor comprising a second gate region, wherein the second nanosheet transistor is stacked over the first nanosheet transistor; and
a conductive contact disposed between the first nanosheet transistor and the second nanosheet transistor, wherein the conductive contact contacts a surface of the first gate region and a surface of the second gate region, wherein the surface of the second gate region is disposed opposite the surface of the first gate region.

20. The semiconductor device of claim 19, wherein the conductive contact is disposed between a channel layer of the first nanosheet transistor and a channel layer of the second nanosheet transistor.
